(19) United States
(12) Patent Application Publication
(10) Pub. No.: US 2017/0343636 A1
(43) Pub. Date: Nov. 30, 2017

(54) MAGNETIC RESONANCE APPARATUS AND METHOD FOR SUPPORTING MONITORING OF A MAGNETIC RESONANCE EXAMINATION OF A PATIENT

(71) Applicant: Siemens Healthcare GmbH, Erlangen (DE)

(72) Inventor: Maria Kroell, Erlangen (DE)

(73) Assignee: Siemens Healthcare GmbH, Erlangen (DE)

(21) Appl. No.: 15/607,810

(22) Filed: May 30, 2017

(30) Foreign Application Priority Data
May 30, 2016 (DE) 102016209297.9

(51) Int. Cl. G01R 33/567

(52) U.S. Cl. CPC G01R 33/567

(57) ABSTRACT

In a method for supporting a monitoring of a magnetic resonance examination on a patient using a magnetic resonance apparatus, the magnetic resonance examination of the patient is started and a monitoring processor determines current examination information of the ongoing magnetic resonance examination. The current examination information are compared with predefined values in the monitoring processor, and a warning is generated if there is a variation between the current examination information and the predefined values. The warning is presented at a display in communication with the monitoring processor.

### BACKGROUND OF THE INVENTION

### Field of the Invention

The present invention concerns a method for supporting monitoring of a magnetic resonance examination of a patient and a magnetic resonance apparatus for implementing such a method.

### Description of the Prior Art

During a magnetic resonance examination of a patient, it is difficult for operating personnel overseeing the magnetic resonance examination, for instance a physician or a medical technical assistant (MTA), to obtain the current status of the magnetic resonance examination with respect to the quality of the recorded magnetic resonance data. Only after completing a magnetic resonance sequence can the operating person overseeing the magnetic resonance examination verify the quality of the recorded magnetic resonance data. This results in a longer examination duration for the patient because, if the quality of the recorded image data is inadequate, the measurement and/or a measuring step has to be carried out again.

### SUMMARY OF THE INVENTION

An object of the present invention is to support operating personnel in order to monitor an ongoing of a magnetic resonance examination of a patient.

The invention for supporting monitoring of an imaging magnetic resonance examination of a patient using a magnetic resonance apparatus (i.e., the scanner thereof) has the following steps.

The magnetic resonance examination of the patient is started, and then current examination information of the ongoing magnetic resonance examination is determined by a monitoring processor. The current examination information are compared in the monitoring processor with predefined values. A warning is generated by the monitoring processor if there is a variation between the current examination information and the predefined values. The warning is presented at a display in communication with the monitoring processor.

The monitoring processor is preferably included in the magnetic resonance apparatus or integrated within the magnetic resonance apparatus. In particular, the monitoring processor is integrated at least partially within a system control computer of the magnetic resonance apparatus. The monitoring processor can include a sensor and/or a camera for recording patient information and/or patient movements. Furthermore, the monitoring processor can include a computing unit, which records information and/or parameters and/or settings of the magnetic resonance apparatus. The current examination information may be patient information and/or device (scanner) information for a current and/or an imminent measurement and/or an imminent measuring step, for instance a magnetic resonance sequence, of the magnetic resonance examination. The current examination information may also include image information of currently recorded image data.

The predefined values preferably represent a permissible variation from ideal values, in particular a permissible variation between the current examination information and the ideal values, for the magnetic resonance examination or for individual measurements and/or individual measuring steps of the magnetic resonance examination. For instance, the predefined values can be a maximum permissible movement of a body part of the patient and/or a maximum permissible noise in the image data and/or maximum intensity differences in the image data, etc. The predefined values can also include a breathing state of the patient, such as a breath-holding state.

With the inventive method, medical operating personnel are supported when monitoring a magnetic resonance examination of a patient. In particular, the medical operating personnel can be notified directly of possible faults and/or deficiencies during the magnetic resonance examination, so that a continuous, time-consuming search for fault sources need not be undertaken during the magnetic resonance examination. Moreover, upon an incorrect implementation of the magnetic resonance examination, the inventive method enables the examination to be interrupted and/or terminated prematurely in order to correct the possible faults. This enables a shorter measuring time for the patient and thus an increased patient throughput, since there is no need to wait until the end of the magnetic resonance examination in order to discover and/or correct faults that have occurred during the magnetic resonance examination.

Furthermore, in an embodiment of the invention a current measurement and/or a current measuring step is automatically terminated prematurely if there is a variation between the current examination information and the predefined values. Thus an examination time for the patient can be reduced in the presence of faulty examination data. The fault that has resulted in the faulty examination data can be corrected. Moreover, the prematurely terminated measuring step and/or the prematurely terminated measurement is preferably started again.

In a further embodiment of the invention, an item of movement information of the patient is recorded in order to determine the current examination information. In this way a body region of the patient to be examined can be monitored with respect to unwanted movements. Imaging data recorded during excessive movements can be rapidly identified in this way and the relevant measuring step repeated.

If the movement information represents a breathing movement of the patient, the movement information can be used to compare a breathing cycle of the patient with breathing commands and/or a breath-holding period during a measurement and/or a measuring step, and acquisition of data during an incorrect breathing phase of the patient can be immediately determined from faulty image data as a possible fault source. In particular, in the case of variations between the breathing cycle of breathing commands and/or of the breath-holding period, individual measuring steps can be repeated immediately and/or the measuring step and/or the measurement can be correspondingly lengthened until the desired concordance is reached between the breathing cycle of the patient and the breathing command and/or the breath-holding period. Moreover, faults in the set-up of a measuring step can also be identified on the basis of the recorded breathing phase of the patient, for instance if no automatic breathing commands were selected for an examination in the abdomen of the patient.

In an embodiment of the invention, the monitoring processor generates image analysis data from an analysis of the current examination information that takes place during the current examination information. On the basis of the image data analysis data that are already present before the end of the examination, the operator can be notified of a poor image quality and/or a possible fault source can be identified. For instance, the image data analysis data can indicate the presence of a blur, such as blurred layers, and/or have excessive noise and/or excessive intensity differences. Thus the image data can be inspected directly and faulty and/or unusable image data can be immediately identified and the operator notified.

Furthermore, the invention concerns a magnetic resonance apparatus, which has a magnetic resonance data acquisition scanner designed to record magnetic resonance image data, and a monitoring processor in communication with a display. The monitoring processor is configured to implement the method for supporting monitoring of magnetic resonance examination of a patient by starting the magnetic resonance examination and determining current examination information of the magnetic resonance examination, comparing the current examination information with predefined values generating a warning if there is a variation between the current examination information and the predefined values, and presenting the warning at the display.

With the inventive magnetic resonance apparatus, medical operating personnel are supported when monitoring a magnetic resonance examination on a patient. In particular, possible faults and/or deficiencies during the magnetic resonance examination can be notified directly to the medical operating personnel so that a continuous, time-consuming search for fault sources need not be undertaken during the magnetic resonance examination. Moreover, upon an incorrect implementation of the magnetic resonance examination, the examination can be interrupted and/or terminated prematurely in order to correct the possible faults. This enables a shorter measuring time for the patient and thus an increased patient throughput, since there is no need to wait until the end of the magnetic resonance examination in order to discover and/or correct faults that have occurred during the magnetic resonance examination.

The advantages of the inventive magnetic resonance apparatus essentially correspond to the advantages of the inventive method for supporting monitoring of a magnetic resonance examination of a patient, as explained above in detail. Features, advantages or alternative embodiments mentioned above are also applicable to the apparatus.

In an embodiment of the invention, the monitoring processor has a breathing sensor. In this way an alignment of a breathing phase of the patient with a breathing command and/or an expected breathing state of the patient of a current examination can be achieved, and the operator can be immediately notified of variations by means of emitting the warning. Moreover, faults in the set-up of a measuring step can also be identified on the basis of the recorded breathing phase of the patient, for instance if no automatic breathing commands were selected for an examination in the abdomen of the patient.

In a further embodiment of the invention, the monitoring processor has a motion sensor. In this way an unwanted movement of the patient can be detected and/or identified immediately and a corresponding warning can be output to the operator. Moreover, the corresponding measuring step and/or the corresponding measurement can be terminated immediately and restarted.

In a further embodiment of the invention, the monitoring processor has an image analysis unit. This allows a deficient quality in the recorded image data and/or a possible fault source to be identified on the basis of already existing image data analysis data. For instance, the image data analysis data can indicate the presence of a blur, for instance blurred layers, and/or excessive noise and/or excessive intensity differences. In this way the recorded image data can be inspected directly and faulty and/or unusable image data can be immediately identified and/or the operator notified.

The present invention also encompasses a non-transitory, computer-readable data storage medium encoded with programming instructions, the storage medium being directly loadable into a programmable computer of a magnetic resonance apparatus, and the programming instructions then causing the computer to implement the method according to the invention as described above, when the programming instructions are executed by the computer.

The programming instructions may be in the form of source code, which must still be compiled and assembled, or which must only be interpreted, or can be an executable software code which needs only to be loaded into the computer for execution thereof.

### BRIEF DESCRIPTION OF THE DRAWINGS

FIG. 1 schematically illustrates an inventive magnetic resonance apparatus.

FIG. 2 is a flowchart of the inventive method for supporting monitoring of a magnetic resonance examination of a patient.

### DESCRIPTION OF THE PREFERRED EMBODIMENTS

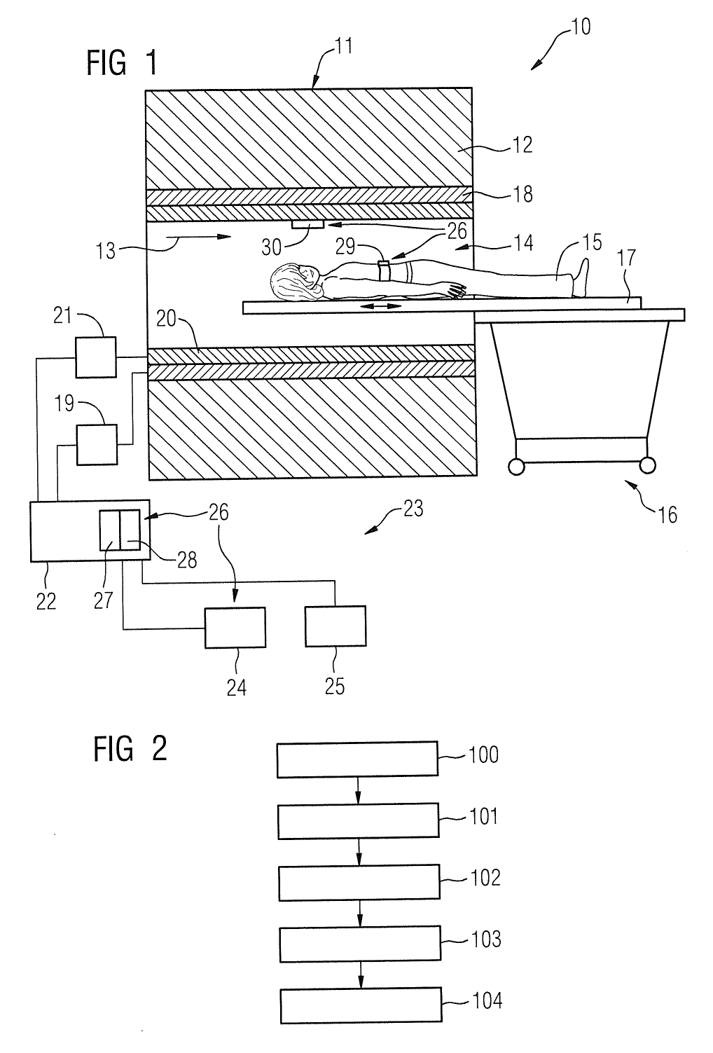

FIG. 1 is a schematic representation of a magnetic resonance apparatus 10. The magnetic resonance apparatus 10 has a scanner 11, which includes a superconducting basic field magnet 12 for generating a strong and constant basic magnetic field 13. The scanner 11 has a patient receiving region 14 for receiving a patient 15. In the exemplary embodiment, the patient receiving region 14 is cylindrical and is peripherally surrounded by the scanner 11. In principle, however, a design of the patient receiving region 14 that deviates therefrom is readily conceivable. The patient 15 can be moved into the patient receiving region 14 by a patient support 16. For this purpose the patient support 16 has a patient bed 17 that is movable within the patient receiving region 14.

The scanner 11 also has a gradient coil arrangement 18 for generating magnetic field gradients that are used for spatially encoding the magnetic resonance signals during imaging. The gradient coil arrangement 18 is operated by a gradient controller 19 of the magnetic resonance apparatus 10. The scanner 11 furthermore has a radio-frequency antenna 20 operated by a radio-frequency antenna controller 21 so as to radiate radio-frequency magnetic resonance sequences into an examination space that is substantially formed by the patient receiving region 14 of the scanner 11. The radiated radio-frequency sequence excites certain nuclear spins in the patient 15, thereby deflecting the excited nuclear spins by a designated flip angle from the direction of the basic magnetic field 13. As these deflected nuclear spins relax in order to return to the steady state, they emit radio-frequency signals, which are the aforementioned magnetic resonance signals. The magnetic resonance signals are detected by the same, or a different, radio-frequency antenna from which the radio-frequency signals were radiated.

The magnetic resonance apparatus 20 has a system control computer 22 that controls the basic field magnet 12, the gradient controller 19 and the radio-frequency antenna controller 21. The system control computer 22 controls the magnetic resonance apparatus 10 centrally, such as for the execution of a predetermined gradient echo imaging sequence. Moreover, the system control computer 22 has an evaluation unit (not shown) for evaluating medical image data recorded during the magnetic resonance examination. Furthermore, the magnetic resonance apparatus 10 has a user interface 23, which is connected to the system control computer 22. Control information such as, for example, imaging parameters and reconstructed magnetic resonance images can be displayed on a display 24, for example on at least one monitor, of the user interface 23 for medical operating personnel. In addition, the user interface 23 has an input unit 25 via which information and/or parameters can be entered by the medical operating personnel during a scanning procedure.

The magnetic resonance apparatus 10 has a monitoring processor 26 for supporting an operator when monitoring during a magnetic resonance examination on the patient 15. The monitoring processor 26 has a computing unit 27 with an image analysis unit 28, which are integrated within the system control computer 22. Furthermore, the monitoring processor 26 has a breathing sensor 29 and a motion sensor 30 in order to record and/or monitor a movement and/or a breathing movement of the patient 15 during the magnetic resonance examination. The motion sensor 30 is preferably arranged within the patient receiving region 14. The breathing sensor 29 can have a breathing belt for instance, and is preferably arranged directly on the patient 15. Furthermore, the display 24 forms a part of the monitoring processor 26.

FIG. 2 shows an inventive method for supporting a monitoring of a magnetic resonance examination on a patient 15. The method is implemented by the monitoring processor 26. To this end the monitoring processor 26 has computer programs and/or software designed to implement the method, which are stored in a memory (not shown) of the monitoring processor 26. The computer programs and/or software are executed by a processor unit (not shown in more detail).

In a first method step 100 of the inventive method, the magnetic resonance examination of the patient 15 is started. The magnetic resonance examination on the patient 15 includes individual measurements and/or measuring steps, and the individual measurements and/or measuring steps can include different sequences. The magnetic resonance examination can also have just one single measurement and/or one single measuring step.

A current item of examination information is then determined by the monitoring processor 26 in a further method step 101. The current examination information can be an item of movement information which is determined by the motion sensor 30 of the monitoring processor 26. Furthermore, the current examination information can also include a breathing movement, which is recorded and/or determined by the breathing sensor 29 of the monitoring processor 26.

The current monitoring information can also be determined by means of the image analysis unit 28 on the basis of image analysis data. In such cases the current examination information can have a noise and/or a noise component, which is identified in the image analysis data, which is made available by the image analysis unit 28. Alternatively or in addition, the current examination information can have intensity differences represented in the image analysis data and/or the occurrence of a blur identified in the image analysis data. Current image analysis data are made available to the image analysis unit 28, and the image analysis data are determined from the recorded image data.

In a further method step 102, the current examination information is compared with predefined values by the monitoring processor 26. The predefined values preferably represent a permissible variation from ideal values for the magnetic resonance examination or for individual measurements and/or individual measuring steps of the magnetic resonance examination. For instance, the predefined values can be a maximum permissible movement of a body part of the patient 15 and/or a maximum permissible noise in the image data and/or maximum intensity differences in the image data etc.

In a further method step 103, a warning is generated by the monitoring processor 103. The warning is generated only if there is a variation between the current examination information and the predefined values. For instance, a warning is generated if a breathing of the patient 15 was measured even though the measurement provides for a breath-holding phase. Furthermore, a warning can be generated if, during a measuring step and/or a measurement, an excessive movement of the patient 15 was registered. Moreover, a warning can be generated if a noise and/or a noise component in the image analysis data is too great and/or excessive intensity differences are present in the image analysis data and/or an excessive blur is present in the image analysis data etc.

In a further method step 104, the generated warning is presented to the operator by the display 24. The warning can be displayed in a separate window on a monitor and/or screen for instance, in particular a monitoring screen. In addition to displaying and/or otherwise presenting the warning, if there is a variation between the current examination information and the predefined values, a current measurement and/or a current measuring step can be terminated prematurely and the measurement and/or the measuring step can be started again. In such cases the termination and/or the renewed starting of the measurement and/or the measuring step can take place automatically and/or independently by the monitoring processor 26. A manual termination of the current measurement and/or the current measuring step and/or a manual restart of the measurement and/or the measuring step are also conceivable at any time.

Although modifications and changes may be suggested by those skilled in the art, it is the intention of the Applicant to embody within the patent warranted hereon all changes and modifications as reasonably and properly come within the scope of the Applicant's contribution to the art.

1. A method for supporting monitoring of a magnetic resonance (MR) examination of a subject, comprising:
from a control computer, operating an MR scanner, while a subject is situated therein, to start the MR examination of the subject;
while the MR examination is ongoing, determining current examination information about the MR examination with a monitoring processor;
in the monitoring processor, comparing the current examination information with predetermined values;
in said monitoring processor, generating a warning upon detection of a variation between said current examination information and the predetermined values; and
from the monitoring processor, emitting the warning via a display in communication with the monitoring processor.

2. A method as claimed in claim 1 comprising, upon detection of said variation between the current examination information and the predetermined values, providing a signal from the monitoring processor to the control computer and, from the control computer, automatically terminating the MR examination, or an examination step thereof, prematurely.

3. A method as claimed in claim 2 comprising, from said control computer, restarting the prematurely terminated MR examination or examination step thereof.

4. A method as claimed in claim 1 comprising, with said monitoring processor, detecting movement information of the patient and determining said current examination information from said movement information.

5. A method as claimed in claim 4 comprising determining a breathing movement as said movement information.

6. A method as claimed in claim 1 comprising acquiring ongoing image data from the patient during said ongoing MR examination and, in said monitoring processor, determining image analysis data from said acquired image data, and generating said current examination information using said image analysis data.

7. A method as claimed in claim 6 comprising generating said current examination information from said image data by an image analysis of said image data that identifies a feature of said image data selected from the group consisting of noise, intensity differences, and a blur.

8. A magnetic resonance (MR) apparatus comprising:
an MR data acquisition scanner;
a control computer configured to operate said MR scanner, while a subject is situated therein, to start the MR examination of the subject;
a monitoring processor configure to determine, while the MR examination is ongoing, current examination information about the MR examination;
said monitoring processor being configured to compare the current examination information with predetermined values;
said monitoring processor being configured to generate a warning upon detection of a variation between said current examination information and the predetermined values;
a display in communication with the monitoring processor; and
monitoring processor being configured to emit the warning via said display.

9. An MR apparatus as claimed in claim 8 wherein said monitoring processor comprises a breathing sensor that detects breathing movement of the subject, and wherein said monitoring processor is configured to derive said current examination information based on said breathing movement.

10. An MR apparatus as claimed in claim 8 wherein said monitoring processor comprises a motion sensor that detects movement of the subject, and wherein said monitoring processor is configured to derive said current examination information based on said movement.

11. An MR apparatus as claimed in claim 8 wherein said control computer is configured to acquire ongoing image data of the subject during the ongoing MR examination, and wherein said monitoring processor is configured to perform an image analysis of said image data during the ongoing MR examination in order to produce image analysis data, and wherein said monitoring processor is configured to use said image analysis data in order to generate said current examination information.

12. A non-transitory, computer-readable data storage medium encoded with programming instructions, said storage medium being loaded into a control and monitoring computer system of a magnetic resonance (MR) apparatus that comprises an MR data acquisition scanner, said programming instructions causing said control and monitoring computer system to:
operate an MR scanner, while a subject is situated therein, to start the MR examination of the subject;
while the MR examination is ongoing, determine current examination information about the MR examination with a monitoring processor;
compare the current examination information with predetermined values;
generate a warning upon detection of a variation between said current examination information and the predetermined values; and
emit the warning via a display in communication with the control and monitoring computer system.
